(19) United States
(12) Patent Application Publication
(10) Pub. No.: US 2024/0128331 A1
(43) Pub. Date: Apr. 18, 2024

(54) BOTTOM ENHANCED LINER-LESS VIA CONTACT FOR REDUCED MOL RESISTANCE

(71) Applicant: International Business Machines Corporation, Armonk, NY (US)

(72) Inventors: Ruilong Xie, Niskayuna, NY (US); Chanro Park, Clifton Park, NY (US); Kangguo Cheng, Schenectady, NY (US); Julien Frougier, Albany, NY (US)

(21) Appl. No.: 17/965,254

(22) Filed: Oct. 13, 2022

(51) Int. Cl. H01L 29/417; H01L 23/522; H01L 29/40; H01L 29/45

(52) U.S. Cl. CPC H01L 29/41725; H01L 23/5226; H01L 29/401; H01L 29/45

(57) ABSTRACT

A contact structure having reduced middle-of-the-line (MOL) resistance is provided that includes a source/drain contact which includes a liner and a via contact that is liner-less. The via contact includes a first via portion having a first critical dimension and a second via portion having a second critical dimension that is greater than the first critical dimension. The second critical dimension provides a maximized via contact bottom critical dimension over the source/drain contact, while the first critical dimension provides sufficient area between the first via portion of the via contact and a neighboring electrically conductive structure thus avoiding any shorts between those two elements.

### BACKGROUND

The present application relates to semiconductor technology, and more particularly to a semiconductor structure including a contact structure that includes a source/drain contact that includes a liner and a via contact located above the source/drain contact that is liner-less.

Field effect transistors (FETs) continue to get smaller because of technological improvements in semiconductor fabrication processes. The technological improvements have enabled aggressive down-scaling of FETs, and the aggressive down-scaling has resulted in increased density of electrical components on integrated circuits. However, as FETs get smaller, challenges arise that can negatively impact their utility and performance. One challenge often encountered in semiconductor fabrication, which arises due to down-scaling of FETs, is the ability to provide FETs with low contact resistance. A contact is an interface material between a FET substrate and interconnect wiring, wherein the interconnect wiring is routed to connect a FET to other integrated circuit components distributed on the surface of the substrate. A contact can enhance electrical current flow (i.e., reduce resistance) between substrate and interconnect wiring. However, as surface area of contacts decrease, due to the aggressive down-scaling, contact resistance can increase and cause a reduction of FET performance, such as a reduction in transistor switching speed.

### SUMMARY

A contact structure having reduced middle-of-the-line (MOL) resistance is provided that includes a source/drain contact which includes a liner and a via contact that is liner-less. The via contact includes a first via portion having a first critical dimension and a second via portion having a second critical dimension that is greater than the first critical dimension. The second critical dimension provides a maximized via contact bottom critical dimension over the source/drain contact, while the first critical dimension provides sufficient area between the first via portion of the via contact and a neighboring electrically conductive structure thus avoiding any shorts between those two elements.

In one aspect of the present application, a semiconductor structure is provided. In one embodiment, the semiconductor structure includes a contact structure including a source/drain contact and a via contact, wherein the via contact is located above the source/drain contact and includes a first via portion having a first critical dimension, and a second via portion having a second critical dimension that is greater than the first critical dimension. The structure further includes a source/drain region of a transistor located beneath the contact structure, and an electrically conductive structure located on top of the contact structure and contacting the first via portion of via contact.

In another aspect of the present application, a method of forming a semiconductor structure is provided. In one embodiment of the present application, the method includes forming a contact opening in a first interlayer dielectric material layer that physically exposes a surface of a source/drain region of a transistor. Next, a metal semiconductor alloy layer is formed in the contact opening and on the physically exposed source/drain region. A metal liner and a contact conductive metal are then formed inside and outside of the contact opening. A patterned hard mask is then formed on the contact conductive metal, and the contact conductive metal is patterned utilizing a metal etching process to form a first via portion of a via contact beneath the patterned hard mask. Next, a dielectric spacer is formed along a sidewall of first via portion. An additional metal etch and an over etch are then performed to remove the contact conductive metal and the metal liner located on top of a gate structure of the transistor, wherein a second via portion of the via contact is formed beneath the first via portion of the via contact and the contact conductive metal remaining in the contact opening forms a source/drain contact. The dielectric spacer is then optionally removed, and thereafter a second interlayer dielectric material layer having at least one electrically conductive structure embedded therein is formed, the at least one electrically conductive structure contacts a surface of the first via portion of the via contact.

### BRIEF DESCRIPTION OF THE DRAWINGS

FIG. 1 is a top down view of a device layout that can be used for describing a semiconductor structure in accordance with the present application, the device layout includes a X-X cut, which is along a length wise direction of a semiconductor channel material structure, and a Y-Y cut, which is located in a source/drain area that is located between two adjacent gate structures.

FIGS. 2A-2B are cross sectional views through X-X and Y-Y of FIG. 1, respectively, of an exemplary structure that can be employed in the present application, the exemplary structure includes at least one gate structure located on a surface of semiconductor channel material structure, a source/drain region located on each side of the at least one gate structure and contacting a sidewall of the at least semiconductor channel material structure and a first interlayer dielectric (ILD) material layer located on the source/drain region.

FIGS. 3A-3B are cross sectional views of the exemplary structure shown in FIGS. 2A-2B, respectively, after forming a contact opening in the first ILD material layer that physically exposes a surface of the source/drain region.

FIGS. 4A-4B are cross sectional views of the exemplary structure shown in FIGS. 3A-3B, respectively, after forming a metal semiconductor alloy layer on the physically exposed source/drain region, a metal liner, and a contact conductive metal.

FIGS. 5A-5B are cross sectional views of the exemplary structure shown in FIGS. 4A-4B, respectively, after forming a patterned hard mask on the contact conductive metal, and patterning the contact conductive metal utilizing a metal etching process to form a first via portion of via contact beneath the patterned hard mask, the first via portion of the via contact is located above the source/drain region.

FIGS. 6A-6B are cross sectional views of the exemplary structure shown in FIGS. 5A-5B, respectively, after forming a dielectric spacer along a sidewall of the first via portion of the via contact.

FIGS. 7A-7B are cross sectional views of the exemplary structure shown in FIGS. 6A-6B, respectively, after performing an additional metal etch and an over etch to remove contact conductive metal and the metal liner located on top of the at least one gate structure; these etching steps create a second via portion of the via contact beneath the first via portion of the via contact and a source/drain contact.

FIGS. 8A-8B are cross sectional views of the exemplary structure shown in FIGS. 7A-7B, respectively, after forming a second ILD material layer having at least one electrically conductive structure embedded therein and contacting a surface of the first via portion of the via contact.

FIGS. 9A-9B are cross sectional views of the exemplary structure shown in FIGS. 7A-7B, respectively, after selective growth of a metal layer.

FIGS. 10A-10B are cross sectional views of the exemplary structure shown in FIGS. 9A-9B, respectively, after forming a second ILD material layer having at least one electrically conductive structure embedded therein and contacting a surface of the first via portion of the via contact.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

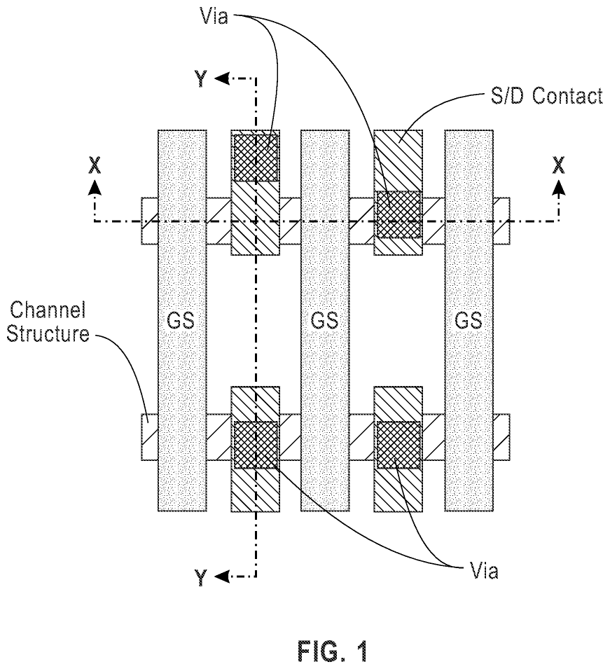

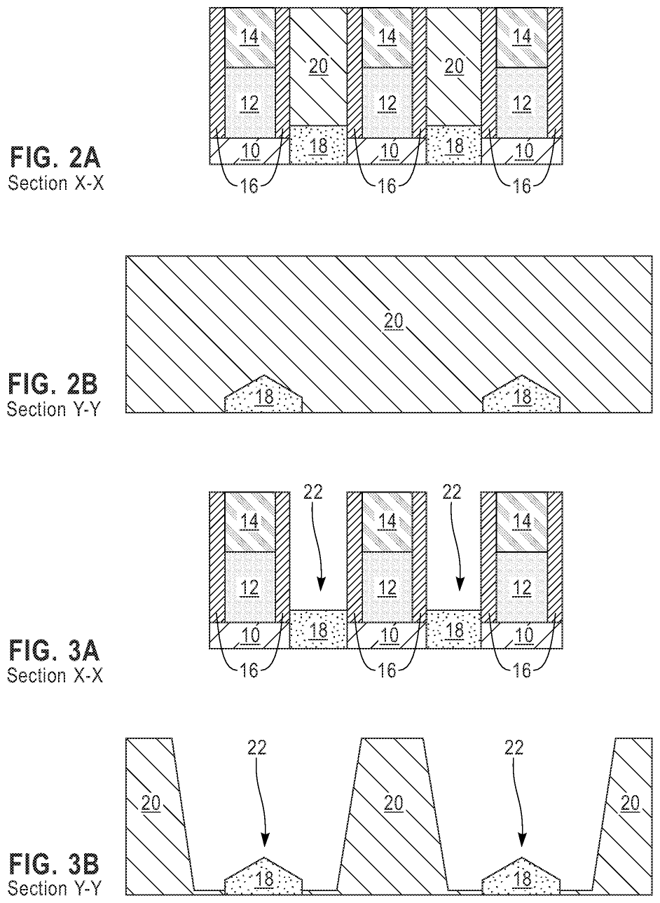

Reference is first made to FIG. 1, which provides a top down view of a device layout that can be used for describing a semiconductor structure in accordance with the present application. By way of illustration, the device layout shows two spaced apart and parallelly orientated channel structures (which corresponds to semiconductor channel material structure 10 below), three spaced apart and parallelly orientated gate structures, GS (which corresponds to gate structure 12 below), that run perpendicular to the channel structures, four source/drain (S/D) contacts (which correlate to source/drain contact 28S), and four via contacts, “Via”; each via contact includes a first via portion and an underlying second via portion, as will be described in greater detail herein below. Each gate structure, GS, crosses over different portions of the two channel structures illustrated in FIG. 1, and a source/drain contact and a via contact are present in a source/drain area that is located between a neighboring pair of gate structures, GS. The device layout illustrated in FIG. 1 includes a X-X cut (which is along a length wise direction of one of the channel structures) and a Y-Y cut (which is located in the source/drain area that is located between two adjacent gate structures, GS). In the present application, each of FIGS. 2A, 3A, 4A, 5A, 6A, 7A, 8A, 9A, and 10A is through cut X-X, while each of FIGS. 2B, 3B, 4B, 5B, 6B, 7B, 8B, 9B, and 10B is through cut Y-Y.

Referring now to FIGS. 2A-2B, there are an exemplary structure that can be employed in the present application. The illustrated exemplary structure of FIGS. 2A-2B includes at least one gate structure 12 located on a surface of semiconductor channel material structure 10, a source/drain region 18 located on each side of the at least one gate structure 12 and contacting a sidewall of the at least semiconductor channel material structure 10 and a first interlayer dielectric (ILD) material layer 20 located on the source/drain region 18. The exemplary structure can also include a gate cap 14 located on top of each gate structure 12 and a gate dielectric spacer 16 located on at least a sidewall of each gate structure 12; the gate dielectric spacer 16 can extend along the corresponding sidewall of the gate cap 14 that is located on top of each gate structure 12. The various components of the exemplary structure shown in FIGS. 2A-2B will now described in more detail herein below. In the present application, the at least one gate structure 12 and the source/drain region 18 are components of a transistor.

The semiconductor channel material structure 10, which serves as a channel region of the transistor, is composed of a semiconductor material having semiconducting properties. Examples of semiconductor materials that can be used to provide the semiconductor channel material structure 10 include, but are not limited to, silicon (Si), a silicon germanium (SiGe) alloy, a silicon germanium carbide (SiGeC) alloy, germanium (Ge), III/V compound semiconductors or II/VI compound semiconductors. The semiconductor channel material structure 10 can be composed of one or more of these semiconductor materials.

In some embodiments of the present application, the semiconductor channel material structure 10 is a topmost semiconductor channel material nanosheet of a vertical stack of spaced apart nanosheets. In such embodiments, each semiconductor channel material nanosheet including the topmost semiconductor channel material nanosheet represented by semiconductor channel material structure 10 in FIG. 2A can have a width from 20 nm to 130 nm, a length from 10 nm to 130 nm, and a vertical height from 4 nm to 20 nm. The semiconductor material that provides each semiconductor channel material nanosheet including the topmost semiconductor channel material nanosheet represented by semiconductor channel material structure 10 in FIG. 2A can be selected to provide either high channel mobility for NFET devices, or high channel mobility for PFET devices.

In some embodiments of the present application, the semiconductor channel material structure 10 is an upper portion of a semiconductor fin. As used herein, a “fin” refers to a contiguous structure including a semiconductor material, such as, for example, silicon, and including a pair of substantially vertical sidewalls that are parallel to each other. As used herein, a surface is “substantially vertical” if there exists a vertical plane from which the surface does not deviate by more than three times the root mean square roughness of the surface. When a semiconductor fin is used as the semiconductor channel material structure 10, the semiconductor fin can have a vertical height from 15 nm to 60 nm and a width from 4 nm to 10 nm.

In yet other embodiments of the present application, the semiconductor channel material structure 10 is a semiconductor nanowire or topmost semiconductor nanowire of a vertical stack of spaced apart semiconductor nanowires. When the semiconductor channel material structure 10 includes a semiconductor nanowire, the semiconductor nanowire can have a vertical thickness from 4 nm to 10 nm, and a width from 4 nm to 10 nm.

Each gate structure 12 includes at least a gate dielectric material layer and a gate electrode; the gate dielectric material layer and the gate electrode are not separately illustrated in the drawings of the present application. As is known, the gate dielectric material layer of the gate structure 12 is in direct contact with the semiconductor channel material structure 10, and the gate electrode is located on the gate dielectric material layer. In some embodiments, the gate structure 12 includes a work function metal (WFM) layer (not shown) located between the gate dielectric material layer and the gate electrode. In other embodiments, the WFM layer is used solely as the gate electrode.

The gate dielectric material layer of the gate structure 12 is composed of a gate dielectric material such as, for example silicon oxide, or a dielectric material having a dielectric constant greater than 4.0 (such dielectric materials can be referred to as a high-k gate dielectric material). All dielectric constants mentioned herein are measured relative to a vacuum unless otherwise noted. Illustrative examples of high-k gate dielectric materials include metal oxides such as, for example, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The high-k gate dielectric material can further include dopants such as lanthanum (La), aluminum (Al) and/or magnesium (Mg).

The gate electrode of the gate structure 12 can include an electrically conductive metal-containing material including, but not limited to, tungsten (W), titanium (Ti), tantalum (Ta), ruthenium (Ru), zirconium (Zr), cobalt (Co), copper (Cu), aluminum (Al), lead (Pb), platinum (Pt), tin (Sn), silver (Ag), or gold (Au), tantalum nitride (TaN), titanium nitride (TiN), tantalum carbide (TaC_{X}), titanium carbide (TiC), titanium aluminum carbide, tungsten silicide (WSi₂), tungsten nitride (WN), ruthenium oxide (RuO₂), cobalt silicide, or nickel silicide.

In some embodiments, a WFM layer can be employed as either the electrically conductive metal-containing material that provides the gate electrode or as a separate layer that is located between the gate dielectric material layer and the gate electrode. The WFM layer can be used to set a threshold voltage of the FET to a desired value. In some embodiments, the WFM layer can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the WFM layer can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof.

The gate cap 14 is composed of a dielectric hard mask material such as, for example, silicon dioxide, silicon nitride and/or silicon oxynitride. In some embodiments, the gate cap 14 can be omitted. When present, the gate cap 14 has at least one sidewall that is vertically aligned with a sidewall of the underlying gate structure 12. Using gate cap 14 is generally preferred since the presence of the same helps to maintain the integrity of the gate structure 12 that is present beneath the gate cap 14 during the various etching steps that are employed in the present application.

The gate dielectric spacer 16 is composed of a gate spacer dielectric material. Examples of gate spacer dielectric materials that can be used in providing the gate dielectric spacer 16 include, but are not limited to, SiN, SiBCN, SiOCN or SiOC. The gate spacer dielectric material that provides the gate dielectric spacer 16 is typically compositionally different from the hard mask dielectric material that provides the gate cap 14. When gate cap 14 is present, the gate dielectric spacer 16 has a topmost surface that is typically coplanar with a topmost surface of the gate cap 14. When gate cap 14 is omitted, the gate dielectric spacer 16 has a topmost surface that is typically coplanar with a topmost surface of the gate structure 12.

Each source/drain region 18 is composed of a semiconductor material and a dopant. As used herein, a “source/drain or S/D” region can be a source region or a drain region depending on subsequent wiring and application of voltages during operation of the field effect transistor (FET). As is known, source/drain regions are located on each side of gate structure 12. The semiconductor material that provides the source/drain region 18 can include one of the semiconductor materials mentioned above for the semiconductor channel material structure 10. The semiconductor material that provides the source/drain region 18 can be compositionally the same as, or compositionally different from, the semiconductor material that provides the semiconductor channel material structure 10. The dopant that is present in the source/drain region 18 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, the source/drain region 18 can have a dopant concentration of from 4×10²⁰ atoms/cm 3 to 3×10²¹ atoms/cm³.

The first ILD material layer 20 can be composed of a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0.

The exemplary structure shown in FIGS. 2A-2B can be formed utilizing well-known processes including for example, a nanosheet FET device process, a finFET device process or a semiconductor nanowire FET device process. So as not to obscure the method that is employed in the present application in forming the bottom liner-less contact structure, the processing employed in the formation of the exemplary structure shown in FIGS. 2A-2B will not be described in detail.

Referring now to FIGS. 3A-3B, there are illustrated the exemplary structure shown in FIGS. 2A-2B, respectively, after forming a contact opening 22 in the first ILD material layer 20 that physically exposes a surface of the source/drain region 18. In embodiments, each contact opening 22 physically exposes a different source/drain region 18. The contact opening 22 can be formed by lithography and etching. Lithography includes forming a photoresist material on a material or a material stack that needs to be patterned, exposing the photoresist material to a desired pattern of irradiation, and then developing the exposed photoresist material. The etching includes a dry etching process or a chemical wet etch process. Dry etching can include reactive ion etching (RIE), ion beam etching (IBE) or plasma etching. Chemical wet etching includes an etchant that is selective in removing a specific material such as, and for formation of the contact opening 22, the first ILD material layer 20.

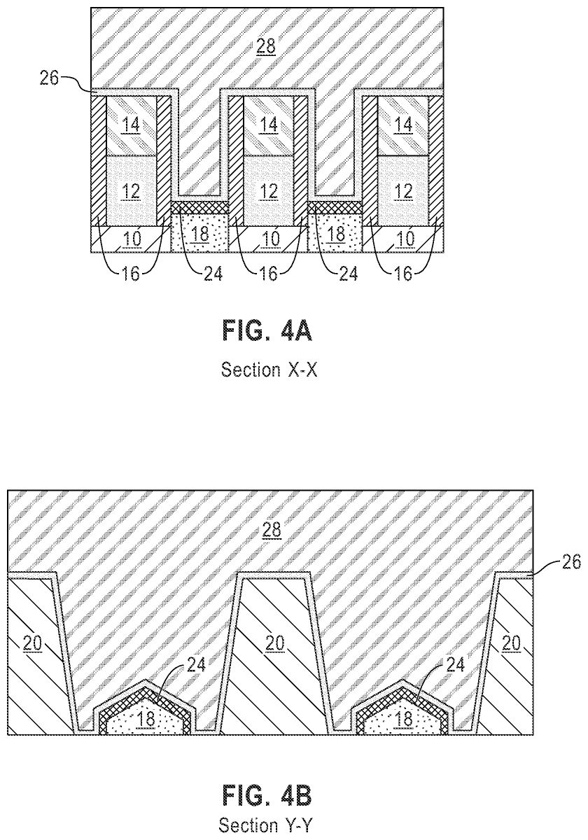

Referring now to FIGS. 4A-4B, there are illustrated the exemplary structure shown in FIGS. 3A-3B, respectively, after forming a metal semiconductor alloy layer 24 on the physically exposed source/drain region, a metal liner 26, and a contact conductive metal 28.

The metal semiconductor alloy layer 24 is composed of a metal and a semiconductor material. The metal component of the metal semiconductor alloy layer 24 includes at least one metal semiconductor alloy forming metal such as, for example, Ni, Co, Pt, W, Ti, Ta, or a rare earth metal (e.g., Er, Yt, La). The semiconductor material component of the metal semiconductor alloy layer 24 typically includes the same semiconductor material as mentioned above from the source/drain regions 18. In one example, the metal semiconductor alloy layer 24 is composed of a silicide of at least one of the above mentioned metal semiconductor alloy forming metals. In another example, the metal semiconductor alloy layer 24 is composed of a germicide of at least one of the above mentioned metal semiconductor alloy forming metals.

The metal semiconductor alloy layer 24 can be formed utilizing a silicidation process that is well known to those skilled in the art. Notably the silicidation process includes first depositing a metal semiconductor alloy forming metal. The depositing of the metal semiconductor alloy forming metal can include, for example, chemical vapor deposition (CVD), plasma enhanced chemical vapor deposition (PECVD), atomic layer deposition (ALD), plating or sputtering. In some embodiments, a co-deposition of metal semiconductor alloy forming metals can be used. In another embodiment, a first metal semiconductor alloy forming metal can be formed, followed by a second metal semiconductor alloy forming metal, which is different from the first metal semiconductor alloy forming metal. The metal semiconductor alloy metal that is formed can have a thickness from 5 to 15 nm. Other thicknesses that are greater than or lesser than the aforementioned thickness range can also be employed as the thickness of the metal semiconductor alloy forming metal.

After providing the metal semiconductor alloy forming metal and in some embodiments of the present application, a diffusion barrier (not shown) can be formed on an exposed upper surface of the metal semiconductor alloy forming metal. In another embodiment of the present application, no diffusion barrier is provided on the exposed upper surface of the metal semiconductor alloy forming metal. When present, the diffusion barrier can include a metal nitride such as, for example, TiN or TaN, and any deposition process including those mentioned above for providing the metal semiconductor alloy forming metal may be used. When present, the diffusion barrier can have a thickness from 1 nm to 20 nm.

A metal semiconductor alloy formation anneal is then performed under conditions that are effective in causing the metal semiconductor alloy forming metal to form the metal semiconductor alloy layer 24. The metal semiconductor alloy formation anneal may be performed in a single step or a two-step anneal can be used. In one embodiment and when nickel is used, the metal semiconductor alloy formation anneal can be performed at a temperature of from 200° C. to 500° C. In another embodiment, temperatures greater than 500° C. can be used. Other temperatures can be used in forming the metal semiconductor alloy layer 24. The metal semiconductor alloy formation anneal is typically performed in an ambient including, for example, argon, helium, neon and/or nitrogen. The metal semiconductor alloy formation anneal can be performed utilizing a rapid thermal anneal, a spike anneal, a microwave anneal or a laser anneal. Following the metal semiconductor alloy formation anneal, the optional diffusion barrier and any unreacted metal semiconductor alloy forming metal can be removed utilizing one or more etch processes. As is shown, the metal semiconductor alloy layer 24 is formed only on physically exposed surfaces of the source/drain regions 18.

After forming the metal semiconductor alloy layer 24, the metal liner 26 is formed. The metal liner 26 is a continuous liner that is formed on physically exposed surfaces of each of the metal semiconductor alloy layer 24, the gate dielectric spacers 16, the gate cap 14, if the same is present, and the first ILD material layer 20. When gate cap 14 is not present, the metal liner 26 can be formed on a physically exposed surface of the gate structure 12. The metal liner 26 includes a metal such as, for example, Ru, TiN, TaN, WN, WC, an alloy thereof, or a stack thereof such as Ti/TiN and Ti/WC. When gate cap 14 is not present, the metal liner 26 must be compositionally different from at least the topmost surface of the gate structure 12. The metal liner 26 can be formed utilizing a conformal deposition process including CVD or ALD. The metal liner 26 that is formed can have a thickness ranging from 1 nm to 5 nm, although lesser and greater thicknesses can also be employed.

After forming the metal liner 26, the contact conductive metal 28 is formed. The contact conductive metal 28 is composed of W, Cu, Al, Co, Ru, Mo, Os, Jr, Rh or an alloy thereof. The contact conductive metal 28 can be formed by any suitable deposition method such as, for example, ALD, CVD, physical vapor deposition (PVD) or plating.

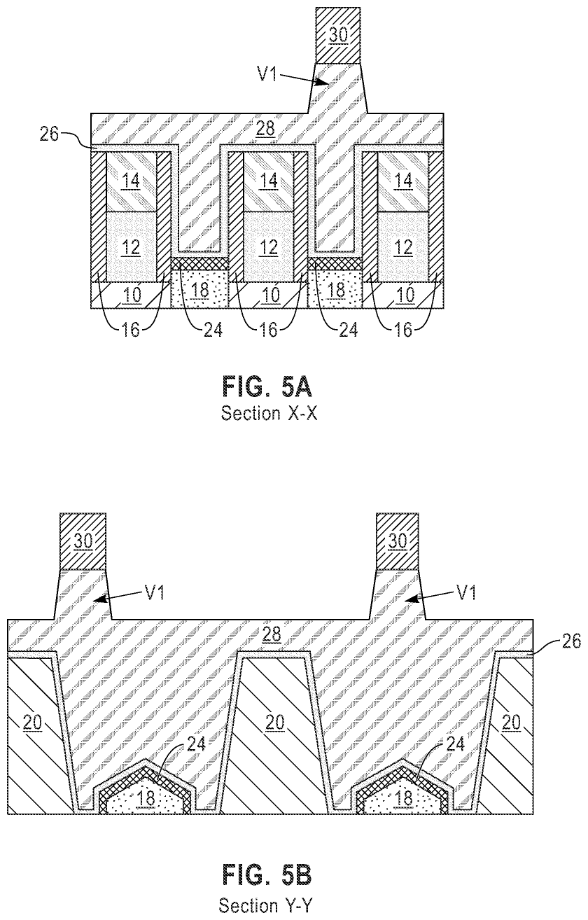

Referring now to FIGS. 5A-5B, there are illustrated the exemplary structure shown in FIGS. 4A-4B, respectively, after forming a patterned hard mask 30 on the contact conductive metal 28, and patterning the contact conductive metal 28 to form a first via portion, V1, of via contact beneath the patterned hard mask 30, the first via portion, V1, of the via contact is located above the source/drain region 18 including the metal semiconductor alloy layer 24. The patterned hard mask 30 is composed of any hard mask material including one of the dielectric hard mask materials mentioned above for the gate cap 14. The patterned hard mask 30 can be formed by first depositing a layer of hard mask material, and thereafter patterning the layer of hard mask material by lithography and etching. The deposition of the layer of hard mask material can include, for example, CVD, PECVD, PVD, or ALD.

After forming the patterned hard mask 30, a metal etching process that is selective in removing the contact conductive metal 28 is employed. This metal etching process does not remove an entirety of the contact conductive metal 28 that is not protected by the patterned hard mask 30. Thus, this metal etch process can be referred to herein as a “partial via etch” Instead, this etching process reduces the height of the non-protected portion of the contact conductive metal 28 as is shown in FIGS. 5A-5B. In one example, this etch includes a RIE.

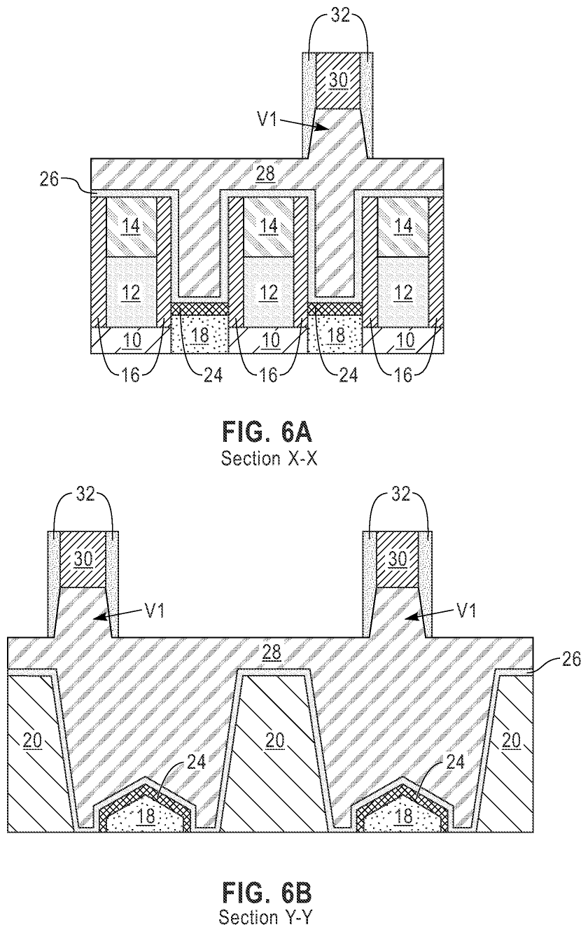

Referring now to FIGS. 6A-6B, there are illustrated the exemplary structure shown in FIGS. 5A-5B, respectively, after forming a dielectric spacer 32 along a sidewall of the first via portion, V1, of the via contact as well as the patterned hard mask 30. The dielectric spacer 32 is composed of any spacer dielectric material including one of the gate spacer dielectric materials mentioned above for the gate dielectric spacer 16. The spacer dielectric material that provides the dielectric spacer 32 is typically, but necessarily always, compositionally different from the gate spacer dielectric material that provides the gate dielectric spacer 16. The dielectric spacer 32 can be formed by deposition of the spacer dielectric material, followed by a spacer etch.

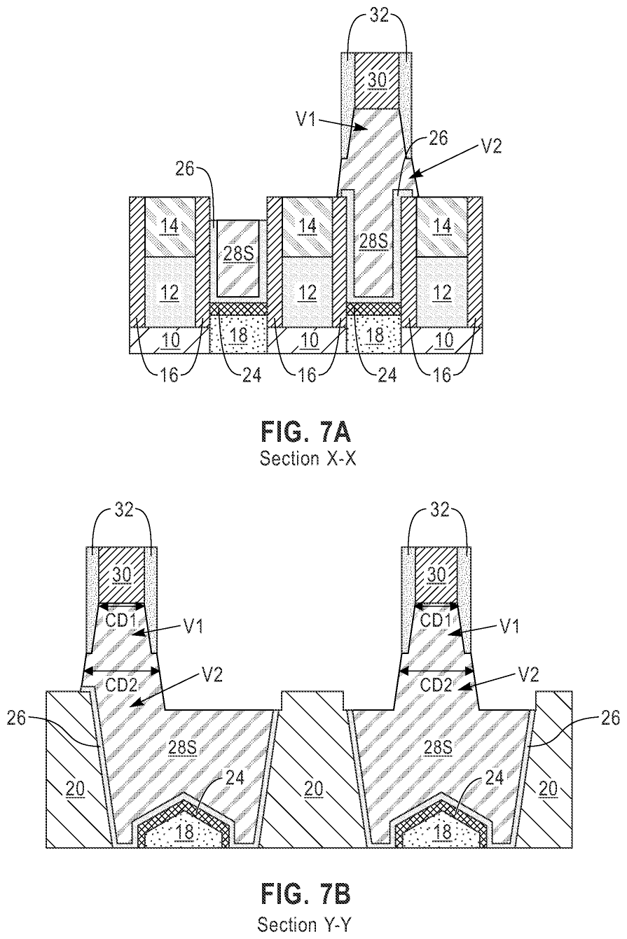

Referring now to FIGS. 7A-7B, there are illustrated the exemplary structure shown in FIGS. 6A-6B, respectively, after performing an additional metal etch and an over etch to remove contact conductive metal 28 and the metal liner 26 from on top of the at least one gate structure 12. These etch processes utilize the dielectric spacer 32 and the patterned hard mask 30 as a combined etch mask. As is shown in FIGS. 7A-7B, this step of the present application creates a second via portion, V2, of the via contact beneath the first via portion, V1, of the via contact. Further, this step of the present application also creates source/drain contact 28S. Collectively, the source/drain contact 28S and the least one via contact (including the first via portion, V1, and the second via portion, V2), form a contact structure of the present application. The contact structure of the present application is of unitary construction without any breaks and/or material interfaces between the source/drain contact 28S and the via contact (including the first via portion, V1, and the second via portion, V2). As can be seen in FIGS. 7A and 7B, a kinked surface exists between the first and second via portions. By “kinked surface” it is meant that is a bend along the sidewalls between the first via portion, V1, and the second via portion, V2.

As is shown, the first via portion, V1, and the second via portion, V2, of the via contact do not include any metal liner located along the sidewalls thereof. Thus, the via contact including the first via portion, V1, and the second via portion, V2, are liner-less. The source/drain contact 28S does however include metal liner 26. Metal liner 26 is present at least along a sidewall of the source/drain contact 28S; in the illustrated embodiment, the metal liner 26 is also present along a bottom wall of source/drain contact 28S. As is shown in FIGS. 7A-7B, the source/drain contact 28S is embedded in the first ILD material layer 20 and is located between each gate structure 12.

The second via portion, V2, of the via contact has a second critical dimension, CD2, that is greater than the first critical dimension, CD1, of the first via portion, V1, of the via contact. In the present application, the critical dimensions, CD1 and CD2, refers to a lateral width of the first and second via portions of the via contact. In one example, the CD1 can be from 10 nm to 20 nm, while CD2 can be from 15 nm to 40 nm.

The additional metal etch includes one of the etching processes mentioned above in providing the exemplary structure shown in FIGS. 5A-5B. The over etch can be the same etch as the additional metal etch or a different etch than the additional metal etch. The over etch removes the metal liner 26 that is present on top of the gate dielectric spacer 16 and the gate cap 14 (or the gate structure 12 if gate cap 14 is not present).

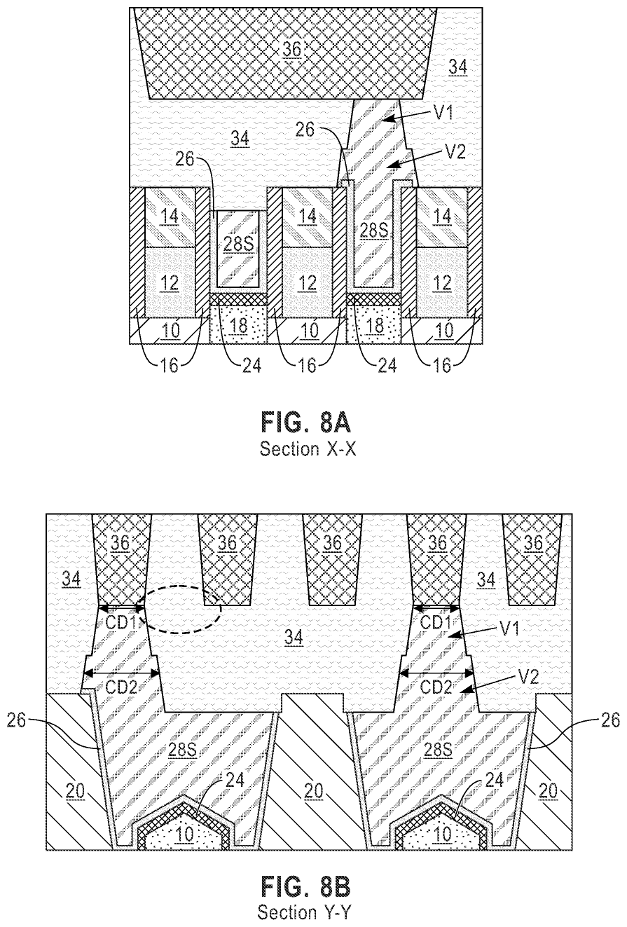

Referring now to FIGS. 8A-8B, there are illustrated the exemplary structure shown in FIGS. 7A-7B, respectively, after forming a second ILD material layer 34 having at least one electrically conductive structure 36 embedded therein and contacting a surface of the via contact. Notably, the at least one electrically conductive structure 36 contacts a topmost surface of the first via portion, V1, of the via contact. In the present application, the second ILD material layer 34 embeds both the first via portion, V1, and the second via portion, V2, of the via contact as well as the at least one electrically conductive structure 36.

It is noted that prior to forming the second ILD material layer 34, the dielectric spacer 32 and the patterned hard mask cap 30 are removed. In some embodiments, the dielectric spacer 32 can remain in the structure. The dielectric spacer 32 can be removed utilizing an etching process that is selective in removing the dielectric spacer 32. The patterned hard mask cap 30 can be removed utilizing an etching process that is selective in remove the patterned hard mask cap 30.

After the removing at least the patterned hard mask cap 30, and optionally, the dielectric spacer 32, the second ILD material layer 34 is formed. The second ILD material layer 34 includes one of the dielectric materials mentioned above for the first ILD material layer 20. The dielectric material that provides the second ILD material layer 34 can be compositionally the same as, or compositionally different from, the dielectric material that provides the first ILD material layer 20. The second ILD material layer 34 can be formed by a deposition process such as, for example, CVD, PECVD, ALD, or spin-on coating.

The at least one electrically conductive structure 36 can be formed utilizing any well-known metallization process; the metallization process can include forming an opening in the second ILD material layer 34, filling the opening with an electrically conductive material as defined herein below, and performing a planarization process. The at least one electrically conductive structure 36 is composed of electrically conductive material such as, for example, Cu, Co, W, or Ru. In some embodiments (not shown), a thin metal adhesion liner can be present along the sidewall and bottom wall of the at least one electrically conductive structure 36. As is shown and after performing the metallization process, the at least one electrically conductive structure 36 has a topmost surface that is coplanar with a topmost surface of the second ILD material layer 34.

As is shown in FIGS. 8A-8B, the via contact including both the first via portion, V1, and second via portion, V2, is liner-less, while the source/drain contact 28S includes metal liner 26. This aspect of the present application aids in reducing the resistance of the contact structure. Further, the second via portion, V2, of the via contact provides a maximized via contact bottom critical dimension, i.e., CD2, over the source/drain contact 28S. Furthermore, the critical dimension, i.e., CD1, of the first via portion, V1, of the via contact is not enlarged thus providing a sufficient area between the first via portion, V1 and a neighboring electrically conductive structure 36; this area is represented by area that is between the dotted oval shown in FIG. 8B. The latter feature avoids shorting of the first via portion, V1, of the via contact to the neighboring electrically conductive structure 36.

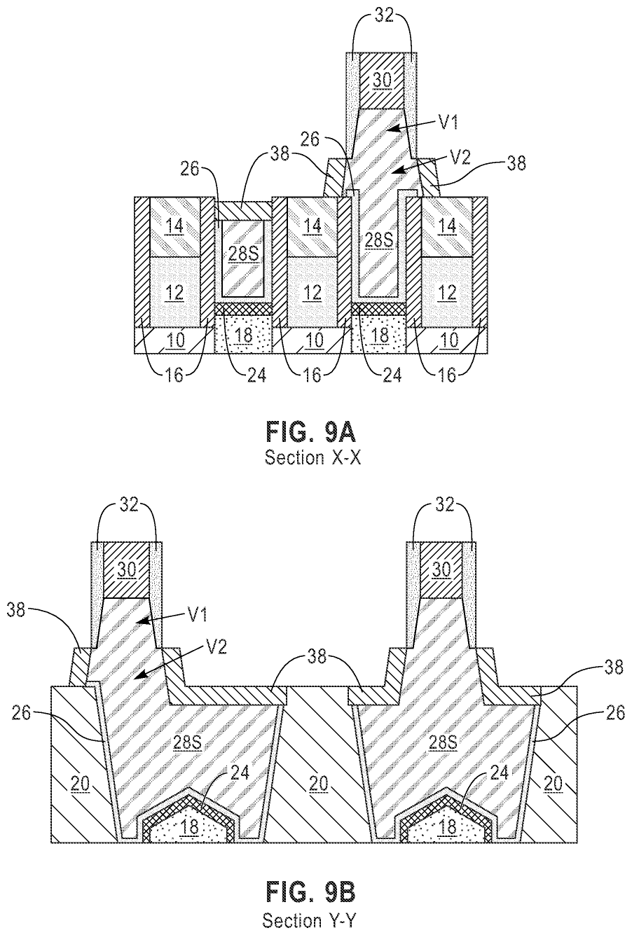

Referring now to FIGS. 9A-9B, there are shown the exemplary structure shown in FIGS. 7A-7B, respectively, after selective growth of a metal layer 38. The presence of metal layer 38 enhances the bottom connection and recovers any metal loss in the underlying source/drain contact 28S; it also adds to CD2. The metal layer 38 includes one of the metals mentioned above in forming the contact conductive metal 28, i.e., W, Cu, Al, Co, Ru, Mo, Os, Ir, Rh or an alloy thereof. The metal layer 38 can be compositionally the same as, or compositionally different from, the metal that provides the contact conducive metal 28. The metal layer 38 is formed by a selective metal growth process such as, for example, selective W, selective Co or selective Ru deposition from exposed metal surfaces of the source/drain contact 28S and the second via portion V2. The metal layer 38 is located along a sidewall of the second via portion, V2 (and thus adds to CD2), but not along a sidewall of the first via portion, V1. The metal layer 38 is also located on a horizontal surface of the source/drain contact 28S.

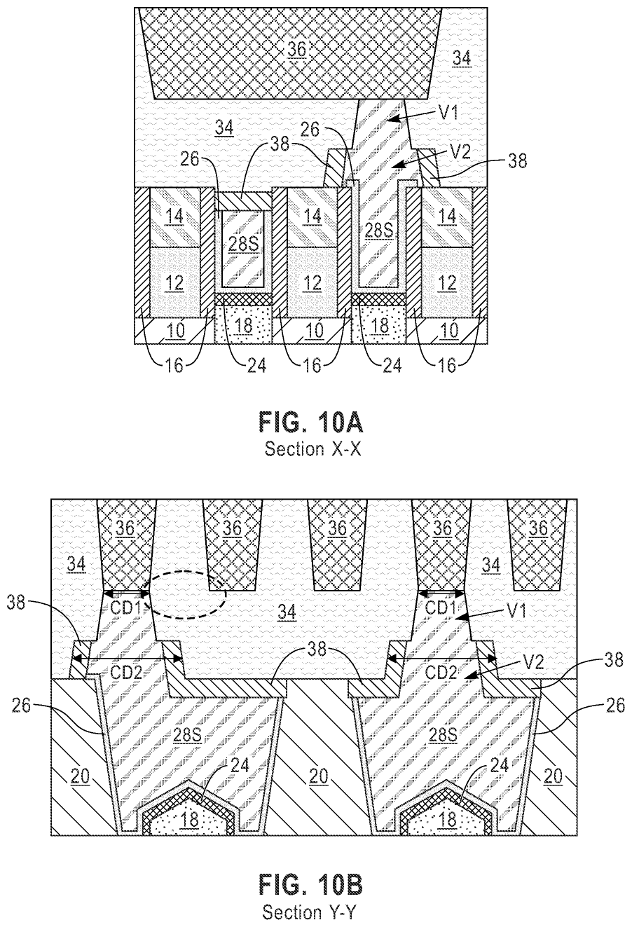

Referring now to FIGS. 10A-10B, there are shown the exemplary structure shown in FIGS. 9A-9B, respectively, after forming a second ILD material layer 34 having at least one electrically conductive structure 36 embedded therein and contacting a surface of the via contact. Notably, the at least one electrically conductive structure 36 contacts a topmost surface of the first via portion, V1, of the via contact. It is noted that prior to forming the second ILD material layer 34, at least the patterned hard mask cap 30 (and optionally the dielectric spacer 32) is removed. The dielectric spacer 32 can be removed utilizing an etching process that is selective in removing the dielectric spacer 32. The patterned hard mask cap 30 can be removed utilizing an etching process that is selective in remove the patterned hard mask cap 30. The second ILD material layer 34 and the at least one electrically conductive structure 36 include materials and are formed as described above in providing the second ILD material layer 34 and the at least one electrically conductive structure 36 to the exemplary structure shown in FIGS. 8A-8B above.

As is shown in FIGS. 10A-10B, the via contact including both the first via portion, V1, and second via portion, V2, is liner-less, while the source/drain contact 28S include metal liner 26. Again, this aspect reduces the resistance of the contact structure. Further, the second via portion, V2, of the via contact provides a maximized via contact bottom critical dimension, i.e., CD2, over the source/drain contact 28S. Furthermore, the critical dimension, i.e., CD1, of the first via portion, V1, of the via contact is not enlarged thus providing a sufficient area between the first via portion, V1 and a neighboring electrically conductive structure 36; this area is represented by area that is between the dotted oval shown in FIG. 8B. The latter feature avoids shorting of the first via portion, V1, of the via contact to the neighboring electrically conductive structure 36. Note that in this embodiment, CD2 includes the width of both the second via portion, V2, and the metal layer 38 that is located along the sidewalls of the second via portion, V2.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a contact structure comprising a source/drain contact and a via contact, wherein the via contact is located above the source/drain contact and includes a first via portion having a first critical dimension, and a second via portion having a second critical dimension that is greater than the first critical dimension;
a source/drain region of a transistor located beneath the contact structure; and
an electrically conductive structure located on top of the contact structure and contacting the first via portion of the via contact.

2. The semiconductor structure of claim 1, wherein the first via portion is located on top of the second via portion, and both the first via portion and the second via portion of the via contact are liner-less.

3. The semiconductor structure of claim 2, further comprising a metal liner present along at least a sidewall of the source/drain contact.

4. The semiconductor structure of claim 1, wherein the source/drain contact is spaced apart from the source/drain region by at least a metal semiconductor alloy layer.

5. The semiconductor structure of claim 1, wherein the source/drain region contacts a sidewall of a semiconductor channel material structure, the semiconductor channel material structure is located beneath a gate structure of the transistor.

6. The semiconductor structure of claim 5, wherein the semiconductor channel material structure comprises a vertical stack of spaced apart nanosheets.

7. The semiconductor structure of claim 5, wherein the semiconductor channel material structure comprises a semiconductor fin.

8. The semiconductor structure of claim 5, wherein the semiconductor channel material structure comprises at least one semiconductor nanowire.

9. The semiconductor structure of claim 1, wherein the source/drain contact is embedded in a first interlayer dielectric material layer.

10. The semiconductor structure of claim 9, further comprising a second interlayer dielectric material layer located above the first interlayer dielectric material layer, wherein the second interlayer dielectric material layer embeds the first via portion and the second via portion of the via contact and the electrically conductive structure.

11. The semiconductor structure of claim 10, wherein the electrically conductive structure has a topmost surface that is coplanar with a topmost surface of the second interlayer dielectric material layer.

12. The semiconductor structure of claim 1, further comprising a metal layer located along a sidewall of the second via portion of the via contact and on a horizontal surface of the source/drain contact.

13. The semiconductor structure of claim 12, wherein the metal layer is composed of a compositionally same contact metal as the contact structure.

14. The semiconductor structure of claim 12, wherein the metal layer is composed of a compositionally different contact metal as the contact structure.

15. The semiconductor structure of claim 1, wherein the source/drain contact and the via contact including the first via portion and the second via portion are of unitary construction.

16. A method of forming a semiconductor structure, the method comprising:
forming a contact opening in a first interlayer dielectric material layer that physically exposes a surface of a source/drain region of a transistor;
forming a metal semiconductor alloy layer in the contact opening and on the physically exposed source/drain region;
forming a metal liner and a contact conductive metal inside and outside of the contact opening;
forming a patterned hard mask on the contact conductive metal;
patterning the contact conductive metal utilizing a metal etching process to form a first via portion of a via contact beneath the patterned hard mask;
forming a dielectric spacer along a sidewall of the first via portion;
performing an additional metal etch and an over etch to remove the contact conductive metal and the metal liner located on top of a gate structure of the transistor, wherein a second via portion of the via contact is formed beneath the first via portion of the via contact and the contact conductive metal that remains in the contact opening forms a source/drain contact; and
forming a second interlayer dielectric material layer having at least one electrically conductive structure embedded therein, the at least one electrically conductive structure contacts a surface of the first via portion of the via contact.

17. The method of claim 16, wherein the first via portion has a first critical dimension, and the second via portion has a second critical dimension that is greater than the first critical dimension.

18. The method of claim 16, wherein the first via portion and the second via portion of the via contact are liner-less, while the metal liner is present along a sidewall and a bottom wall of the source/drain contact.

19. The method of claim 16, further comprising selectively depositing a metal layer along a sidewall of the second via portion of the via contact and on a horizontal surface of the source/drain contact, wherein the selectively depositing is performed after the performing of the additional metal etch and the over etch and prior to removing the dielectric spacer.

20. The method of claim 19, wherein the source/drain region of the transistor contacts a sidewall of a semiconductor channel material structure that is located beneath the gate structure of the transistor.
